(19) United States
(12) Patent Application Publication
(10) Pub. No.: US 2025/0218947 A1
(43) Pub. Date: Jul. 3, 2025

(54) INTERCONNECTOR, ELECTRONIC APPARATUS INCLUDING THE INTERCONNECTOR, AND METHOD OF MANUFACTURING THE INTERCONNECTOR

(71) Applicant: SAMSUNG ELECTRONICS CO., LTD., Suwon-si (KR)

(72) Inventors: Youngchul LEEM, Suwon-si (KR); Jeongyub Lee, Suwon-si (KR); Eunhyoung Cho, Suwon-si (KR)

(73) Assignee: SAMSUNG ELECTRONICS CO., LTD., Suwon-si (KR)

(21) Appl. No.: 18/962,989

(22) Filed: Nov. 27, 2024

(30) Foreign Application Priority Data
Jan. 3, 2024 (KR) 10-2024-0001068
Mar. 18, 2024 (KR) 10-2024-0037388

(51) Int. Cl. H01L 23/532; H01L 21/768; H01L 23/522

(52) U.S. Cl. CPC H01L 23/53252; H01L 21/76879; H01L 23/5226; H01L 23/53214; H01L 23/53228; H01L 23/53257

(57) ABSTRACT

Provided is an interconnector including a metal layer, a dielectric layer on the metal layer and including a hole exposing a surface of the metal layer, a reaction inhibitor in the hole and contacting a lateral surface of the dielectric layer, a first ruthenium via in the hole, the first ruthenium via contacting the metal layer and the reaction inhibitor, and a second ruthenium via in the hole, the second ruthenium via contacting the first ruthenium via and the reaction inhibitor, a resistivity of the second ruthenium via being greater than a resistivity of the first ruthenium via.

### CROSS-REFERENCE TO RELATED APPLICATION

This application claims priority to Korean Patent Application No. 10-2024-0001068, filed on Jan. 3, 2024, in the Korean Intellectual Property Office, and Korean Patent Application No. 10-2024-0037388, filed on Mar. 18, 2024, in the Korean Intellectual Property Office, the disclosures of which are incorporated by reference herein in their entireties.

### BACKGROUND

### 1. Field

Embodiments of the present disclosure relate to an interconnector, an apparatus including the interconnector, and a method of manufacturing the interconnector.

### 2. Description of Related Art

Most electronic or semiconductor apparatuses may be manufactured by combining and connecting semiconductors, insulators, and conductors with each other. For example, various integrated circuits may be manufactured by forming a plurality of unit elements on a semiconductor substrate and then repeatedly stacking an insulating layer (interlayer insulating layer) and interconnections on the unit elements.

As the size of electronic or semiconductor apparatuses gradually decreases, high-performance interconnectors are required.

### SUMMARY

One or more example embodiments provide an interconnector having improved electrical characteristics and a method of manufacturing the interconnector.

One or more example embodiments provide a semiconductor apparatus including an interconnector having improved electrical characteristics.

However, aspects of the disclosure are not limited thereto, and other aspects of the disclosure will be apparently understood by those skilled in the art through the following description.

Additional aspects will be set forth in part in the description which follows and, in part, will be apparent from the description, or may be learned by practice of example embodiments of the disclosure.

According to an aspect of an example embodiment, there is provided an interconnector including a metal layer, a dielectric layer on the metal layer and including a hole exposing a surface of the metal layer, a reaction inhibitor in the hole and contacting a lateral surface of the dielectric layer, a first ruthenium via in the hole, the first ruthenium via contacting the metal layer and the reaction inhibitor, and a second ruthenium via in the hole, the second ruthenium via contacting the first ruthenium via and the reaction inhibitor, a resistivity of the second ruthenium via being greater than a resistivity of the first ruthenium via.

A ratio of the resistivity of the second ruthenium via to the resistivity of the first ruthenium via may be from 1.2 to 3.

The resistivity of the second ruthenium via may be less than or equal to 25 μΩ·cm.

A thickness of the first ruthenium via may be less than a thickness of the second ruthenium via.

A ratio of a thickness of the second ruthenium via to a thickness of the first ruthenium via may be from 2 to 20.

The first ruthenium via may have a thickness less than or equal to 1.5 nm.

At least one of a width of the hole and a thickness of the hole may be less than or equal to 10 nm.

The first ruthenium via may be based on reduction, and the second ruthenium via may be based on oxidation.

A size of grains included in the first ruthenium via may be different from a size of grains included in the second ruthenium via.

A size of grains included in the first ruthenium via may be less than a size of grains included in the second ruthenium via.

An arithmetic average roughness (Ra) of the second ruthenium via may be less than or equal to 1 nm.

At least one of the first ruthenium via and the second ruthenium via may not have an empty space.

An oxide of a metal of the metal layer may not be included in the hole.

The metal layer may include at least one of copper (Cu), aluminum (Al), cobalt (Co), tungsten (W), ruthenium (Ru), and molybdenum (Mo).

The reaction inhibitor may include at least one of tris(dimethylamino)methylsilane (TDMAMS), bis(N,N-dimethylamino)-dimethylsilane (DMADMS), dimethylamino-trimethylsilane (DMATMS), tert-Butyl chloride, tert-Butyl bromide, and tert-Butyl iodide.

According to another aspect of an example embodiment, there is provided an electronic apparatus including a device layer including at least one of a transistor, a capacitor, and a resistor, and an interconnector connected to the device layer, the interconnector including a metal layer, a dielectric layer on the metal layer and including a hole exposing a surface of the metal layer, a reaction inhibitor in the hole and contacting a lateral surface of the dielectric layer, a first ruthenium via in the hole, with the first ruthenium via contacting the metal layer and the reaction inhibitor, and a second ruthenium via in the hole, with the second ruthenium via contacting the first ruthenium via and the reaction inhibitor, a resistivity of the second ruthenium via being greater than a resistivity of the first ruthenium via.

According to still another aspect of an example embodiment, there is provided a method of manufacturing an interconnector, the method including forming a dielectric layer on a metal layer, the dielectric layer including a hole, forming a first ruthenium via in the hole based on a reducing reaction gas, and forming a second ruthenium via in the hole based on an oxidizing reaction gas, wherein a resistivity of the first ruthenium via is less than a resistivity of the second ruthenium via.

The method may further include forming a reaction inhibitor on a lateral surface of the dielectric layer that is exposed through the hole.

The resistivity of the second ruthenium via may be less than or equal to 25 μΩ·cm.

A thickness of the first ruthenium via may be less than or equal to 1.5 nm.

### BRIEF DESCRIPTION OF THE DRAWINGS

The above and other aspects, features, and advantages of example embodiments of the disclosure will be more apparent from the following description taken in conjunction with the accompanying drawings, in which:

FIG. 1 is a view schematically illustrating an electronic apparatus including an interconnector according to an example embodiment;

FIG. 2 is a cross-section illustrating an interconnector that is part of an interconnector layer shown in FIG. 1;

FIG. 3A is high-angle annular dark field (HAADF) image of a ruthenium via formed on a metal layer by using oxygen as a reaction gas according to a related example;

FIG. 3B is an atomic force microscope (AFM) image illustrating a surface of a ruthenium via formed on a metal layer by using oxygen as a reaction gas according to a related example;

FIG. 4 is a graph illustrating a relationship between the thickness and resistivity of a ruthenium via formed on a metal layer by using hydrogen as a reaction gas according to an example embodiment;

FIG. 5 is a view illustrating the thickness and resistivity of an oxidation-based ruthenium via with respect to a process time, according to an example embodiment;

FIG. 6A is an HAADF image of a ruthenium via formed on a metal layer by sequentially using hydrogen and oxygen according to an example embodiment;

FIG. 6B is an AFM image illustrating a surface of a ruthenium via formed on a metal layer by sequentially using hydrogen and oxygen according to an example embodiment;

FIGS. 7A, 7B, 7C, 7D, and 7E are views illustrating a method of manufacturing the interconnector shown in FIG. 2;

FIG. 8 is a view illustrating an interconnector according to another embodiment;

FIGS. 9A, 9B, 9C, 9D, and 9E are views illustrating a method of manufacturing the interconnector shown in FIG. 8;

FIG. 10 is a plan view illustrating a three-dimensional semiconductor device according to an embodiment; and

FIGS. 11A, 11B, and 11C are cross-sectional views respectively taken along lines A-A′, B-B′, and C-C′ of FIG. 10.

### DETAILED DESCRIPTION

Reference will now be made in detail to embodiments, examples of which are illustrated in the accompanying drawings, wherein like reference numerals refer to like elements throughout. In this regard, the example embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, interconnectors and apparatuses including the interconnectors will be described according to various embodiments with reference to the accompanying drawings. In the drawings, like reference numerals refer to like elements, and the sizes of elements may be exaggerated for clarity of illustration.

The terms of a singular form may include plural forms unless otherwise mentioned. It will be further understood that the terms “comprises” and/or “comprising” used herein specify the presence of stated features or elements, but do not preclude the presence or addition of one or more other features or elements. In the drawings, the sizes or thicknesses of elements may be exaggerated for clarity of illustration. In addition, when a material layer is referred to as being “above” or “on” a substrate or another layer, it may be directly on the substrate or the other layer while making contact with the substrate or the other layer or may be above the substrate or the other layer with a third layer therebetween. In the following descriptions of the embodiments, a material of each layer is merely an example, and another material may be used.

In the disclosure, terms such as “unit” or “module” may be used to denote a unit that has at least one function or operation and is implemented with hardware, software, or a combination of hardware and software.

Specific executions described herein are merely examples and do not limit the scope of the disclosure in any way. For simplicity of description, other functional aspects of conventional electronic configurations, control systems, software and the systems may be omitted.

Furthermore, line connections or connection members between elements depicted in the drawings represent functional connections and/or physical or circuit connections by way of example, and in actual applications, they may be replaced or embodied as various additional functional connections, physical connections, or circuit connections.

An element referred to with the definite article or a demonstrative determiner may be construed as the element or the elements even though it has a singular form.

Expressions such as “at least one” preceding a list of elements specify the entire list of elements and do not specify individual elements within the list. For example, expressions such as “at least one selected from A, B, and C” or “at least one selected from the group consisting of A, B, and C” may be interpreted as indicating only A, only B, only C, or any combination of two or more of A, B, and C such as ABC, AB, BC, and AC.

When terms such as “approximately” or “substantially” are used in relation to a numerical value, the numerical value may be interpreted as including manufacturing or operational variations from the numerical value (for example, a variation of ±10%). Furthermore, when terms such as “generally” and “substantially” are used in relation to geometric shapes, geometric precision may not be required, and permissible variations of the geometric shapes may be within the scope of embodiments. In addition, regardless of whether numerical values or shapes are qualified or described by “approximately” or “substantially,” the numerical values or shapes may be interpreted as including manufacturing or operational variations from the numerical values or shapes (for example, a variation of ±10%).

It will be understood that although terms such as “first” and “second” are used herein to describe various elements, these elements should not be limited by these terms. These terms are only used to distinguish one element from other elements.

Examples or exemplary terms are just used herein to describe technical ideas and should not be considered for purposes of limitation unless defined by the claims.

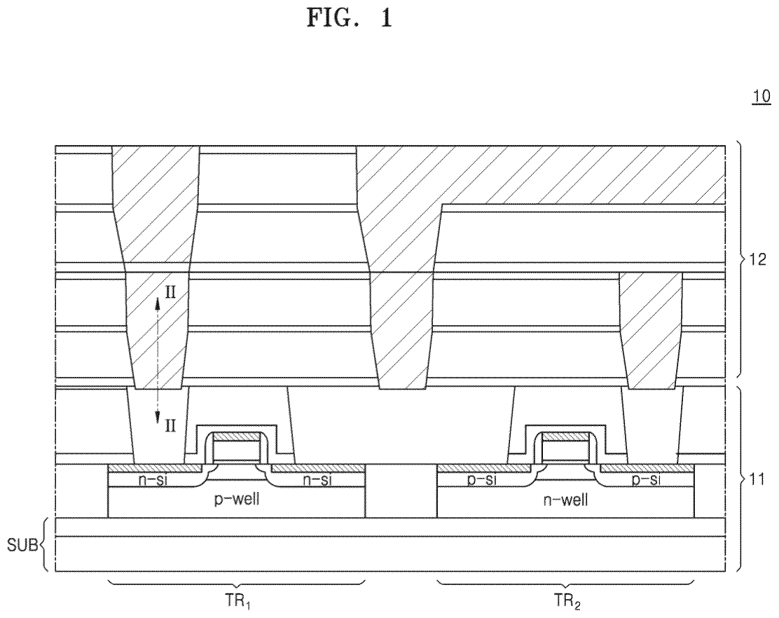

FIG. 1 is a view schematically illustrating an electronic apparatus 10 including interconnectors according to an example embodiment. Referring to FIG. 1, the electronic apparatus 10 includes a device layer 11 and an interconnector layer 12 connected to the device layer 11.

The device layer 11 may include a substrate SUB. For example, the substrate SUB may include a Group IV semiconductor material, a group III/V semiconductor compound, or a group II/VI semiconductor compound. For example, the substrate SUB may include silicon (Si), germanium (Ge), silicon carbide (SiC), silicon germanium (SiGe), silicon germanium carbide (SiGeC), Ge Alloy, gallium arsenide (GaAs), indium arsenide (InAs), indium phosphide (InP), or the like. However, the listed materials are merely examples, and various other semiconductor materials may be included in the substrate SUB.

The substrate SUB may include a single layer or multiple layers formed by stacking different materials. The substrate SUB may include, for example, a silicon-on-insulator (SOI) substrate or a silicon-germanium-on-insulator (SGOI) substrate. In addition, the substrate SUB may include a non-doped semiconductor material or a doped semiconductor material.

The device layer 11 may include one or more semiconductor devices such as resistors, diodes, capacitors, and/or transistors. Although FIG. 1 illustrates two transistors TR₁ and TR₂, embodiments are not limited thereto. One or more semiconductor devices may be formed using related techniques. Thus, the device layer 11 may include a memory or display device including a transistor, a capacitor, a diode, a resistor, or the like, and the electronic apparatus 10 may be a system memory, a memory device, a display device, a mobile device, or the like.

The interconnector layer 12 may be disposed on the device layer 11. The interconnector layer 12 may have a structure in which a plurality of metallization layers (interconnectors) are stacked. The interconnectors may each include a metal layer and a dielectric layer.

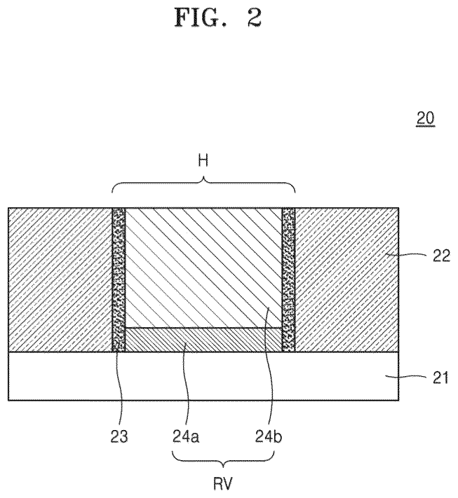

FIG. 2 is a cross-sectional view illustrating an interconnector 20 that is part of the interconnector layer 12 described with reference to FIG. 1.

Referring to FIG. 2, the interconnector 20 may include a metal layer 21, a dielectric layer 22 disposed on the metal layer 21 and including a hole H through which a portion of a surface of the metal layer 21 is exposed, a reaction inhibitor 23 provided in the hole H and contacting a lateral surface of the dielectric layer 22, and a ruthenium via RV provided in the hole H and contacting the metal layer 21 and the reaction inhibitor 23.

The metal layer 21 may include a metal or a metal alloy having high electrical conductivity. For example, the metal layer 21 may include at least one selected from copper (Cu), aluminum (Al), cobalt (Co), tungsten (W), ruthenium (Ru), and molybdenum (Mo). However, embodiments are not limited thereto, and various other metals may be included in the metal layer 21.

The dielectric layer 22 may be disposed on the metal layer 21. The dielectric layer 22 may have a single-layer structure or a multi-layer structure in which different materials are stacked. The dielectric layer 22 may include a material having a low relative dielectric constant. For example, the relative dielectric constant of the dielectric layer 22 may be 4 or less. The dielectric layer 22 may include at least one selected from silicon oxide (SiO₂), silicon nitride (SiN), and silicon carbide (SiC). However, the listed materials are merely examples, and various other dielectric materials may be included in the dielectric layer 22. In addition, the dielectric layer 22 may include an organic dielectric material.

The dielectric layer 22 may include at least one hole H to expose the surface of the metal layer 21. Although FIG. 2 illustrates one hole H formed in the dielectric layer 22, embodiments are not limited thereto. Two or more holes H may be formed in the dielectric layer 22. The width of the hole H may be different from the thickness of the hole H. For example, the width of the hole H may be greater than the thickness of the hole H. For example, at least one selected from the thickness of the hole H and the width of the hole H may be less than or equal to about 15 nm or may be less than or equal to about 10 nm or less.

The interconnector 20 may further include the reaction inhibitor 23 that is provided in the hole H and contacting the lateral surface of the dielectric layer 22. When the ruthenium via RV is formed in the hole H, the reaction inhibitor 23 may guide the ruthenium via RV such that the ruthenium via RV may not grow conformally on bottom and lateral surfaces of the hole H but may grow in a bottom-up manner. Owing to the bottom-up growth of the ruthenium via RV in the hole H, the ruthenium via RV may fill the inside of the hole H without a seam or empty space formed in the hole H.

The reaction inhibitor 23 may include a material that is more easily adsorbed onto the dielectric layer 22 but is hardly adsorbed onto the metal layer 21. The reaction inhibitor 23 may include carbon atoms. For example, the reaction inhibitor 23 may include at least one selected from tris(dimethylamino)methylsilane (TDMAMS), bis(N,N-dimethylamino)-dimethylsilane (DMADMS), and dimethylamino-trimethylsilane (DMATMS).

The interconnector 20 may further include the ruthenium via RV that fills the hole H while contacting the metal layer 21 and the reaction inhibitor 23 inside the hole H. The ruthenium via RV may include ruthenium as a main component. For example, the ruthenium via RV may include ruthenium in an amount of greater than or equal to 95 at %.

The resistivity of the ruthenium via RV may be less than or equal to about 25 μΩ·cm, which allows improved electrical characteristics. In addition, the arithmetic average roughness (Ra) of the ruthenium via RV may be less than or equal to 1 nm, which allows easier interlayer contact.

The ruthenium via RV may include a first ruthenium via 24a that is in contact with the metal layer 21 and the reaction inhibitor 23 in the hole H, and a second ruthenium via 24b that is in contact with the first ruthenium via 24a and the reaction inhibitor 23 in the hole H. The first ruthenium via 24a and the second ruthenium via 24b may be sequentially arranged above the metal layer 21.

The resistivity of the first ruthenium via 24a may be less than the resistivity of the second ruthenium via 24b. For example, the ratio of the resistivity of the second ruthenium via 24b to the resistivity of the first ruthenium via 24a may be from about 1.2 to about 3. The resistivity of the first ruthenium via 24a may be greater than 0 μΩ·cm and less than or equal to about 20 μΩ·cm. The resistivity of the second ruthenium via 24b may be greater than 0 μΩ·cm and less than or equal to about 25 μΩ·cm. However, embodiments are not limited thereto. For example, the resistivity of the first ruthenium via 24a may be from about 8 μΩ·cm to about 20 μΩ·cm, and the resistivity of the second ruthenium via 24b may be from about 8 μΩ·cm to about 25 μΩ·cm.

The thickness of the first ruthenium via 24a may be less than the thickness of the second ruthenium via 24b. For example, the ratio of the thickness of the second ruthenium via 24b to the thickness of the first ruthenium via 24a may be from about 2 to about 20. The thickness of the first ruthenium via 24a may be in the range of greater than about 0 nm to about 1.5 nm. The thickness of the second ruthenium via 24b may be less than 100 nm or may be less than 30 nm.

The first ruthenium via 24a may be formed using a reducing reaction gas and may thus be referred to as a reduction-based layer. The second ruthenium via 24b may be formed using an oxidizing reaction gas and may thus be referred to as an oxidation-based layer. Depending on whether the reducing reaction gas and the oxidizing reaction gas, the size of grains of the first ruthenium via 24a may be different from the size of grains of the second ruthenium via 24b. For example, the size of grains included in the first ruthenium via 24a may be less than the size of grains included in the second ruthenium via 24b.

In an example embodiment, the electrical characteristics of the ruthenium via RV of the interconnector 20 may be improved by forming the ruthenium via RV sequentially using reaction gases having different characteristics. A ruthenium via may be formed on the metal layer 21 by using oxygen as a reaction gas. However, oxygen used as a reaction gas may react with a metal of the metal layer 21 and may thus form a metal oxide at an interface between the metal layer 21 and the ruthenium via. The metal oxide not only deteriorates the electrical characteristics of the ruthenium via, but also increases the surface roughness of the ruthenium via, thereby causing poor interlayer contact.

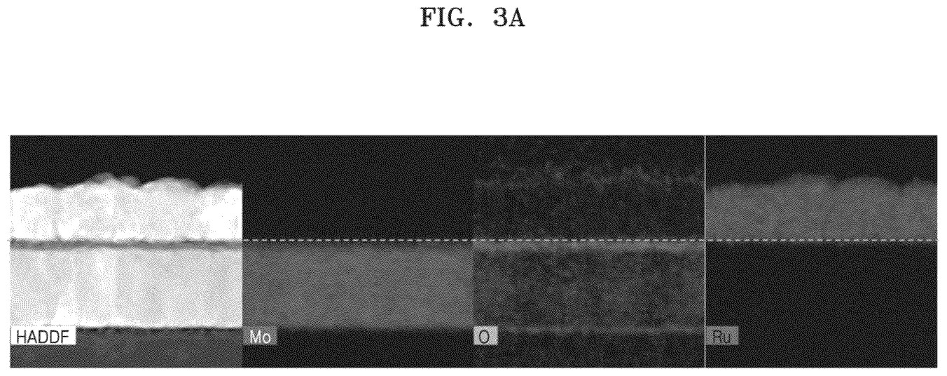

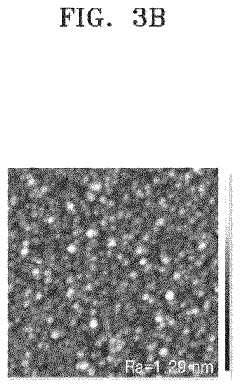

FIG. 3A is high-angle annular dark field (HAADF) image of a ruthenium via formed on a metal layer by using oxygen as a reaction gas according to a related example. The metal layer was formed using molybdenum (Mo). As shown in FIG. 3A, oxygen is detected at an interface between the metal layer and the ruthenium via which indicates that oxygen used as a reaction gas reacted with a metal of the metal layer to form a metal oxide, or that naturally-occurring metal oxide was not removed. The metal oxide deteriorates the electrical characteristics of a metal structure including the ruthenium via.

FIG. 3B is an atomic force microscope (AFM) image illustrating a surface of a ruthenium via formed on a metal layer by using oxygen as a reaction gas according to a related example. The metal layer was formed using molybdenum (Mo). As shown in FIG. 3B, the arithmetic average roughness (Ra) of the ruthenium via is about 1.29 nm, which exceeds 1 nm. This indicates that the arithmetic average roughness of the ruthenium via is due to a metal oxide formed at an interface between the metal layer and the ruthenium via.

According to an example embodiment, in the interconnector 20, the first ruthenium via 24a contacting the metal layer 21 may be formed using a reducing reaction gas. The reducing reaction gas may include at least one selected from hydrogen (H₂), ammonia (NH₃), germanium hydride (GeH₄), hydrazine (N₂H₄), and hydrazine derivatives. Naturally occurring oxides (native oxides) may be present on a surface of the metal layer 21. Some ligands of a ruthenium precursor may be burned off by oxygen on the surface of the metal layer 21, and the ruthenium precursor may be adsorbed on the metal layer 21 through dissociative chemisorption. Hydrogen injected thereafter may generate H₂O vapor by reducing the native oxides, and the H₂O vapor may generate metallic ruthenium by reacting with the chemically adsorbed ruthenium precursor and may continuously regenerate new chemical adsorption sites. In this manner, the first ruthenium via 24a may be formed. However, it is difficult to completely remove the ligands of the ruthenium precursor only through reduction by hydrogen, and thus, the first ruthenium via 24a may be formed only near the surface of the metal layer 21. For example, the first ruthenium via 24a may undergo bottom-up growth on the surface of the metal layer 21. For example, the thickness of the first ruthenium via 24a that is reduction-based via may be 1.5 nm or less.

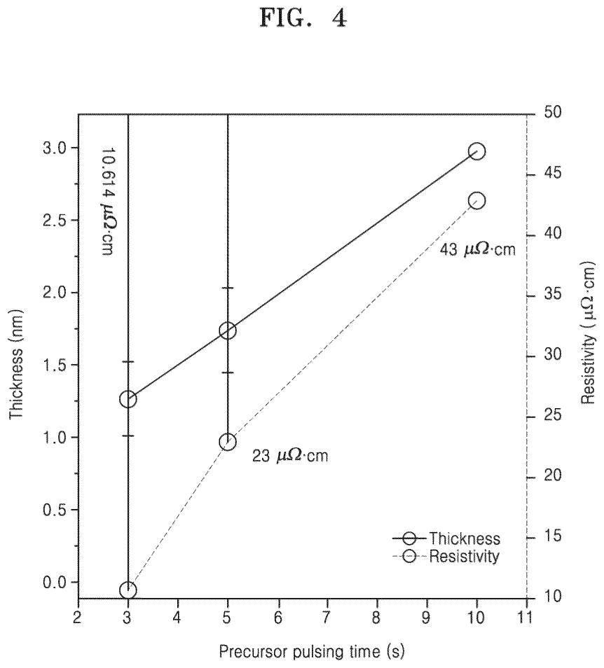

FIG. 4 is a graph illustrating a relationship between the thickness and resistivity of a ruthenium via formed on a metal layer by using hydrogen as a reaction gas according to an example embodiment. FIG. 4 shows that as the injection time of a ruthenium precursor increases, the thickness of the ruthenium via that is a reduction-based via increases. However, it is also shown that as the injection time of the ruthenium precursor increases, the resistivity of the reduction-based ruthenium via increases. This may suggest that there is a limit to metallizing the ruthenium precursor by using hydrogen that is a reducing reaction gas.

As the thickness of the reduction-based ruthenium via increases, the resistivity of the reduction-based ruthenium via increases. Due to this relationship, the reduction-based ruthenium via may be formed only up to a thickness at or below which the reduction-based ruthenium via has resistivity similar to the resistivity of an oxidation-based ruthenium via. For example, the thickness of the reduction-based ruthenium via may be less than or equal to about 1.5 nm.

According to an example embodiment, the interconnector 20 may be formed by forming the first ruthenium via 24a (reduction-based ruthenium via) on the metal layer 21 and then the second ruthenium via 24b (oxidation-based ruthenium via) on the first ruthenium via 24a. The ruthenium via RV may have a relatively low resistivity. The second ruthenium via 24b that is an oxidation-based ruthenium via is formed on the first ruthenium via 24a that is a reduction-based ruthenium via, and thus, reaction between oxygen and a metal included in the metal layer 21 may hardly occur. Therefore, metal oxide (here, the metal refers to the metal included in the metal layer 21) may not be formed.

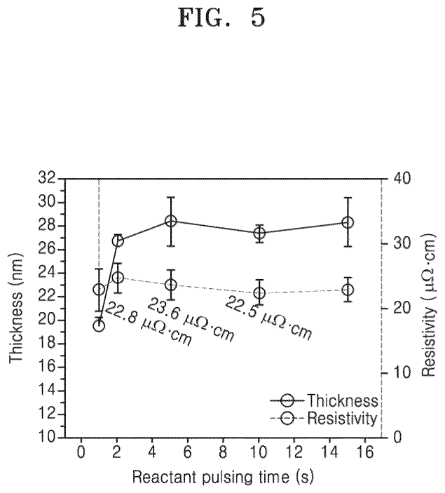

FIG. 5 is a view illustrating the thickness and resistivity of an oxidation-based ruthenium via with respect to a process time, according to an example embodiment. FIG. 5 shows that after a reaction gas is injected for a predetermined time period or more, the thickness and resistivity of the oxidation-based ruthenium via are constant. The thickness and resistivity of the oxidation-based ruthenium vias are saturated after the injection time period of the reaction gas reaches the predetermined time period, and thus, the oxidation-based ruthenium vias may be more easily formed.

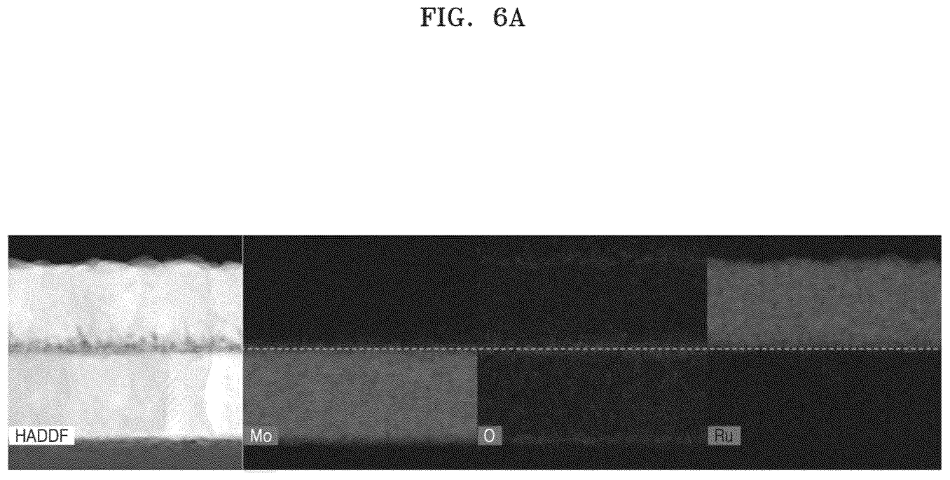

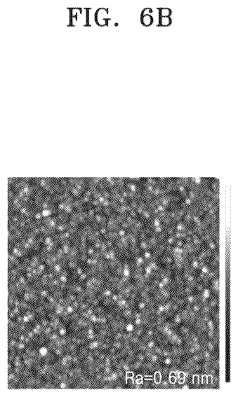

FIG. 6A is an HAADF image of a ruthenium via formed on a metal layer by sequentially using hydrogen and oxygen according to an example embodiment. The metal layer was formed using molybdenum (Mo). As shown in FIG. 6A, almost no oxygen was detected at an interface between the metal layer and the ruthenium via. This suggests that a metal oxide was not formed from a metal of the metal layer due to the use of hydrogen as a reaction gas.

FIG. 6B is an AFM image illustrating a surface of a ruthenium via formed on a metal layer by sequentially using hydrogen and oxygen according to an example embodiment. The metal layer was formed using molybdenum (Mo). As shown in FIG. 6B, the arithmetic average roughness (Ra) of the ruthenium via is 0.69 nm, which is less than about 1 nm. No metal oxide was formed at an interface between the metal layer and the ruthenium via, and thus, the ruthenium via may evenly grown on the metal layer.

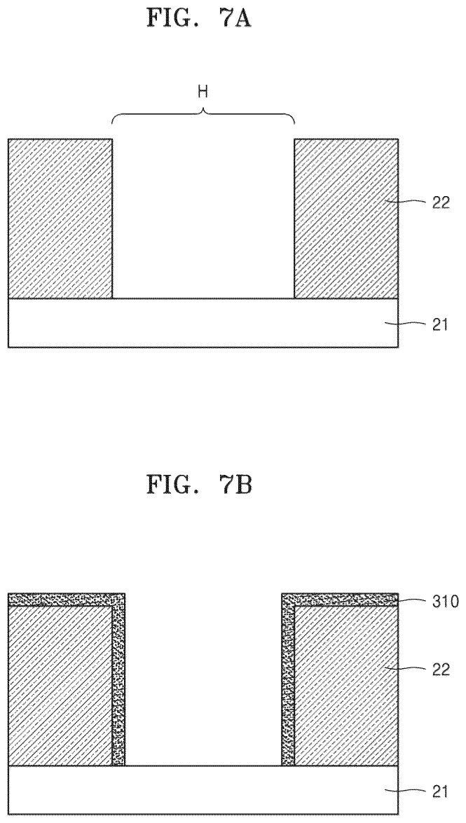

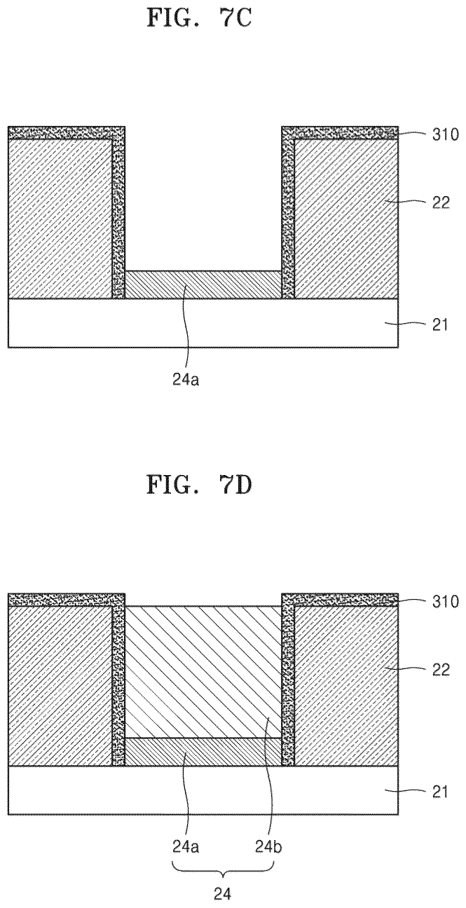

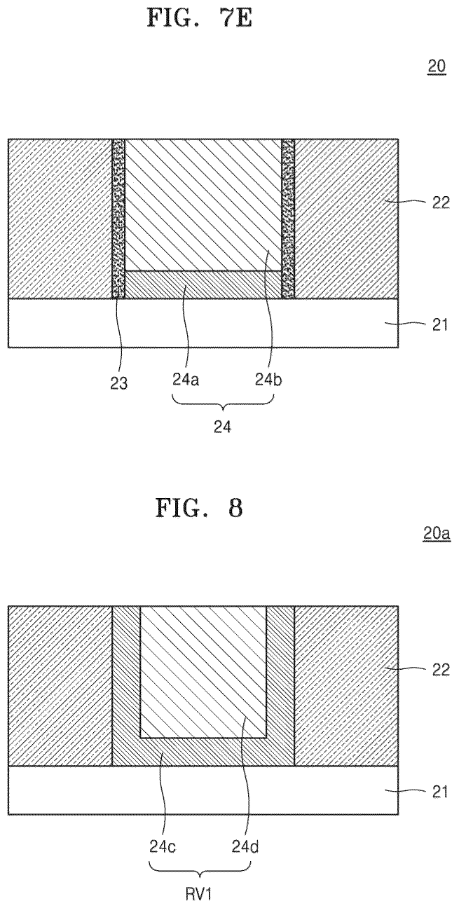

FIGS. 7A to 7E are views illustrating a method of manufacturing the interconnector 20 described with reference to FIG. 2.

Referring to FIG. 7A, a dielectric layer 22 including a hole H may be formed on a metal layer 21. A portion of a surface of the metal layer 21 may be exposed to the outside through the hole H. After forming the dielectric layer 22 on the metal layer 21, a portion of the dielectric layer 22 may be etched to form the hole H. According to another example embodiment, the dielectric layer 22 including the hole H may be formed on the metal layer 21 by using a mask. At least one of the width and the thickness of the hole H may be less than or equal to 10 nm.

Referring to FIG. 7B, a reaction inhibitor 310 may be formed on the dielectric layer 22. The reaction inhibitor 310 may include a material that is more easily adsorbed onto the dielectric layer 22, hardly adsorbed onto the metal layer 21, and does not react with a ruthenium precursor. The reaction inhibitor 310 may include carbon atoms. For example, the reaction inhibitor 310 may include at least one selected from TDMAMS, DMADMS, and DMATMS. However, the reaction inhibitor 310 is not limited thereto.

The reaction inhibitor 310 is formed only on the dielectric layer 22. For example, the reaction inhibitor 310 may be formed on an upper surface of the dielectric layer 22 and a lateral surface of the dielectric layer 22 that is exposed through the hole H. Thus, the portion of the surface of the metal layer 21 may still be exposed to the outside through the hole H.

Referring to FIG. 7C, a first ruthenium via 24a may be formed in the hole H. The first ruthenium via 24a may be formed by an atomic layer deposition process or a chemical vapor deposition process. For example, the first ruthenium via 24a may be formed by injecting a ruthenium precursor into the hole H and then using a reducing reaction gas. The first ruthenium via 24a may be formed at a temperature ranging from room temperature to about 400° C. or less.

The ruthenium precursor may include at least one selected from tricarbonyl(trimethylenemethane)ruthenium [Ru(TMM)(CO)3], bis(ethylcyclopentadienyl)ruthenium(II) [Ru(EtCp)2], bis(2,4-dimethylpentadienyl)ruthenium(II) [Ru(DMPD)2], Dicarbonyl-bis(5-methyl-2,4-hexanediketonato)ruthenium(II) [carish], and (1,3-cyclohexadiene)(ethylbenzene)ruthenium(0) [EBCHDRu]. However, the ruthenium precursor is not limited thereto. The reducing reaction gas may include at least one selected from H₂, NH₃, GeH₄, hydrazine (N₂H₄), and a hydrazine derivative, but is not limited thereto. The first ruthenium via 24a that is a reduction-based via may have a thickness of less than or equal to about 1.5 nm.

The first ruthenium via 24a is formed using the reducing reaction gas in a region of the hole H that is in contact with the metal layer 21, and thus, a metal oxide may not be formed at an interface between the metal layer 21 and the first ruthenium via 24a. A metal contained in the metal oxide may be the same as a metal contained in the metal layer 21.

Referring to FIG. 7D, a second ruthenium via 24b that is an oxidation-based via may be formed on the first ruthenium via 24a. The second ruthenium via 24b may be formed by an atomic layer deposition process or a chemical vapor deposition process. For example, the second ruthenium via 24b may be formed by injecting a ruthenium precursor into the hole H and then using an oxidizing reaction gas. The second ruthenium via 24b may be formed at a temperature ranging from room temperature to about 450° C. or less.

The ruthenium precursor may include at least one selected from tricarbonyl(trimethylenemethane)ruthenium [Ru(TMM)(CO)3], bis(ethylcyclopentadienyl)ruthenium(II) [Ru(EtCp)2], bis(2,4-dimethylpentadienyl)ruthenium(II) [Ru(DMPD)2], dicarbonyl-bis(5-methyl-2,4-hexanediketonato)ruthenium(II) [carish], (1,3-Cyclohexadiene)(ethylbenzene)ruthenium(0) [EBCHDRu], Ru(HD)(iPrMeBe)(0), Ru(EtBe)(CHD)(0), and (ethylbenzene)(1,3-butadiene)Ru(0) [Ru(EtBe)(BD)]. However, the ruthenium precursor is not limited thereto. The oxidizing reaction gas may include at least one selected from O₂, O₃, H₂O, NO, NO₂, N₂O, CO₂, H₂O₂, HCOOH, CH₃COOH, (CH₃CO)₂O, plasma O₂, remote plasma O₂, plasma N₂O, and plasma H₂O. However, the oxidizing reaction gas is not limited thereto.

The thickness of the second ruthenium via 24b may be greater than the thickness of the first ruthenium via 24a. The ratio of the thickness of the second ruthenium via 24b to the thickness of the first ruthenium via 24a may be from about 2 to about 20. The thickness of the second ruthenium via 24b may be less than or equal to 100 nm or may be less than or equal to 30 nm.

Due to the first ruthenium via 24a that is a hydrogen-based ruthenium via, the formation of metal oxides at an interface between the metal layer 21 and the first ruthenium via 24a may be prevented, and a ruthenium via 24 having improved surface roughness may be formed. Due to the second ruthenium via 24b that is an oxidation-based ruthenium via, the ruthenium via 24 may have low resistivity In addition, the ruthenium via 24 may be grown in a bottom-up growth manner by using the reaction inhibitor 310, thereby preventing the formation of an empty space or a seam in the ruthenium via 24 and improving the surface roughness of the ruthenium via 24.

Referring to FIG. 7E, the interconnector 20 may be completely formed by removing the reaction inhibitor 310 from the upper surface of the dielectric layer 22.

FIG. 8 is a view illustrating an interconnector 20a according to another example embodiment. Comparing FIGS. 2 and 8 with each other, the interconnector 20a shown in FIG. 8 may not include the reaction inhibitor 23. In the interconnector 20a shown in FIG. 8, the width of a hole H may be greater than the thickness of the hole H. For example, the width of the hole H may be about 1.5 times to about 3 times the thickness of the hole H.

A ruthenium via RV1 of the interconnector 20a shown in FIG. 8 may include a first ruthenium via 24c provided in the hole H on an upper surface of a metal layer 21 and a lateral surface of a dielectric layer 22, and a second ruthenium via 24d provided on the first ruthenium via 24c to fill the hole H. The first ruthenium via 24c may be a reduction-based layer, and the second ruthenium via 24d may be an oxidation-based layer. The resistivity of the first ruthenium via 24c may be less than the resistivity of the second ruthenium via 24d. For example, the ratio of the resistivity of the second ruthenium via 24d to the resistivity of the first ruthenium via 24c may be from about 1.2 to about 3. The resistivity of the first ruthenium via 24c may be in the range of greater than about 0 μΩ·cm to about 20 μΩ·cm, and the resistivity of the second ruthenium via 24d may be in the range of greater than about 0 μΩ·cm to about 25 μΩ·cm. In addition, the resistivity of the first ruthenium via 24c may be in the range of about 8 μΩ·cm to about 20 μΩ·cm, and the resistivity of the second ruthenium via 24d may be in the range of about 8 μΩ·cm to about 25 μΩ·cm.

The thickness of the first ruthenium via 24c may be less than the thickness of the second ruthenium via 24d. For example, the ratio of the thickness of the second ruthenium via 24b to the thickness of the first ruthenium via 24c may be from about 2 to about 20. The thickness of the first ruthenium via 24c may be in the range of greater than about 0 nm to about 1.5 nm, and the thickness of the second ruthenium via 24d may be 100 nm or less or may be 30 nm or less.

The size of grains included in the first ruthenium via 24c may be different from the size of grains included in the second ruthenium via 24d. For example, the size of grains included in the first ruthenium via 24c may be less than the size of grains included in the second ruthenium via 24d.

Because the first ruthenium via 24c that is reduction-based ruthenium via is in contact with the metal layer 21, the formation of metal oxides between the ruthenium via RV1 and the metal layer 21 may be prevented.

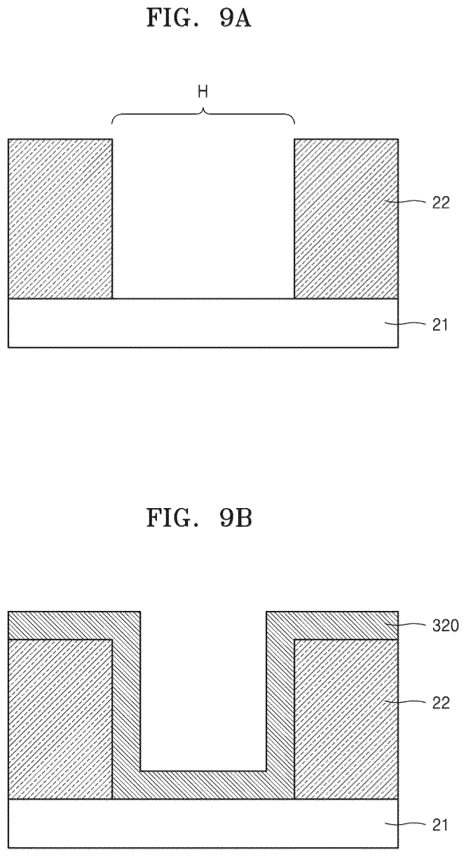

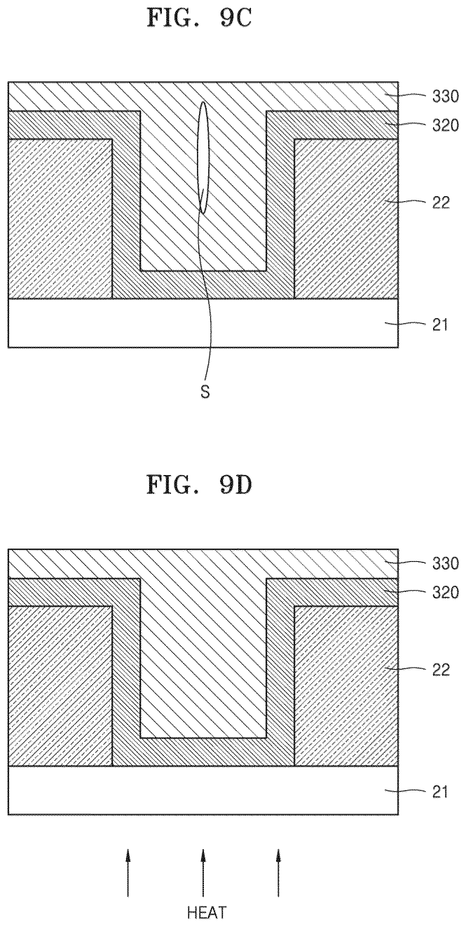

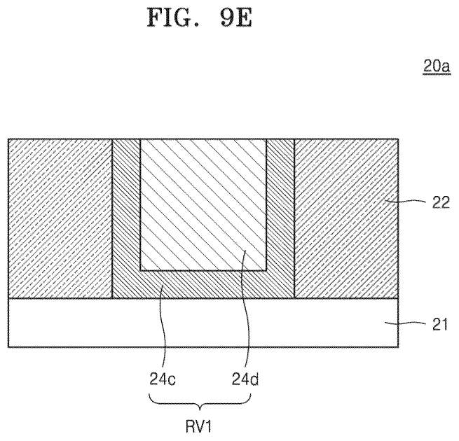

FIGS. 9A to 9E are views illustrating a method of manufacturing the interconnector 20a shown in FIG. 8.

Referring to FIG. 9A, a dielectric layer 22 may be formed on a metal layer 21, and the dielectric layer 22 may include a hole H through which a surface of the metal layer 21 is exposed. After forming the dielectric layer 22 on the metal layer 21, a portion of the dielectric layer 22 may be etched to form the hole H. According to another example embodiment, the dielectric layer 22 including the hole H may be formed on the metal layer 21 by using a mask.

Referring to FIG. 9B, a first ruthenium layer 320 may be formed in the hole H on an upper surface of the dielectric layer 22. The first ruthenium layer 320 may be formed by an atomic layer deposition process or a chemical vapor deposition process. For example, the first ruthenium layer 320 may be formed by injecting a ruthenium precursor into the hole H and then using a reducing reaction gas. The first ruthenium layer 320 may be formed at a temperature ranging from room temperature to less than or equal to about 400° C. The ruthenium precursor and the reducing reaction gas have been described above, and thus, descriptions thereof are omitted.

The first ruthenium layer 320 may be conformally formed in the hole H. That is, the first ruthenium layer 320 may be formed on a bottom surface of the hole H (that is, a surface of the metal layer 21 exposed through the hole H), a lateral surface of the hole H (a lateral surface of the dielectric layer 22 exposed through the hole H), and the upper surface of the dielectric layer 22.

Referring to FIG. 9C, a second ruthenium layer 330 may be formed on the first ruthenium layer 320. The second ruthenium layer 330 may be formed by an atomic layer deposition process or a chemical vapor deposition process. For example, the second ruthenium layer 330 may be formed by injecting a ruthenium precursor into the hole H and then using an oxidizing reaction gas. The second ruthenium layer 330 may fill the hole H. The ruthenium precursor and the oxidizing reaction gas have been described above, and thus, descriptions thereof are omitted.

The second ruthenium layer 330 may be conformally formed on the first ruthenium layer 320. For example, the second ruthenium layer 330 may grow in the hole H not only in a vertical direction but also in a horizontal direction. Therefore, a seam S or an empty space S may be formed in the second ruthenium layer 330.

Referring to FIG. 9D, the second ruthenium layer 330 may be annealed. The annealing temperature of the second ruthenium layer 330 may be greater than a temperature at which the second ruthenium layer 330 is formed. For example, the second ruthenium layer 330 may be reconstructed by annealing the second ruthenium layer at a temperature of about 300° C. to about 500° C., and thus, the seam S or the empty space S formed in the second ruthenium layer 330 may be removed. The first ruthenium layer 320 and the second ruthenium layer 330 may be formed as a single layer through the annealing.

Referring to FIG. 9E, the first ruthenium layer 320 and the second ruthenium layer 330 may be removed from the upper surface of the dielectric layer 22 to form a ruthenium via RV1.

The interconnectors 20 and 20a including the ruthenium vias RV and RV1 may be applied to highly integrated three-dimensional semiconductor devices.

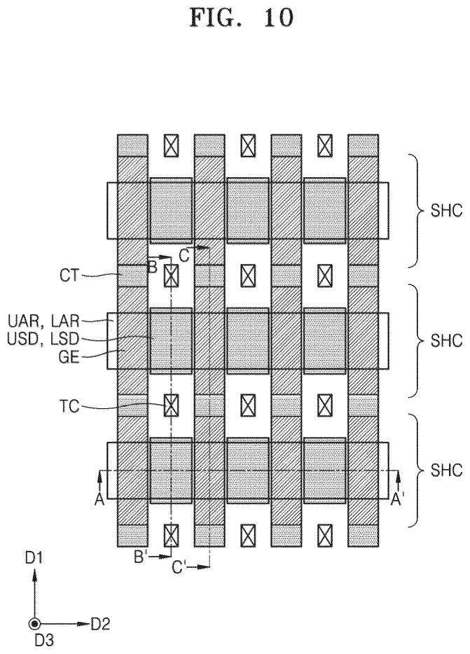

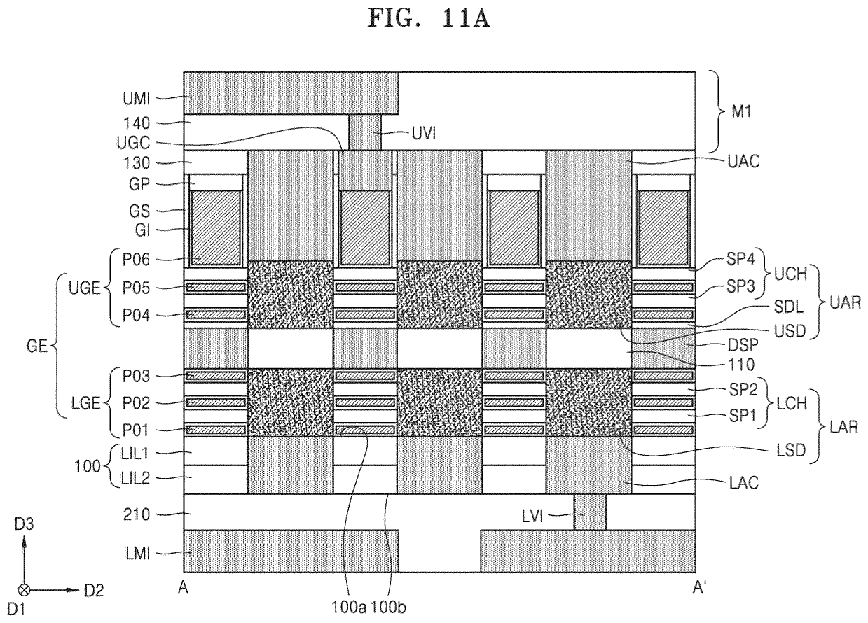

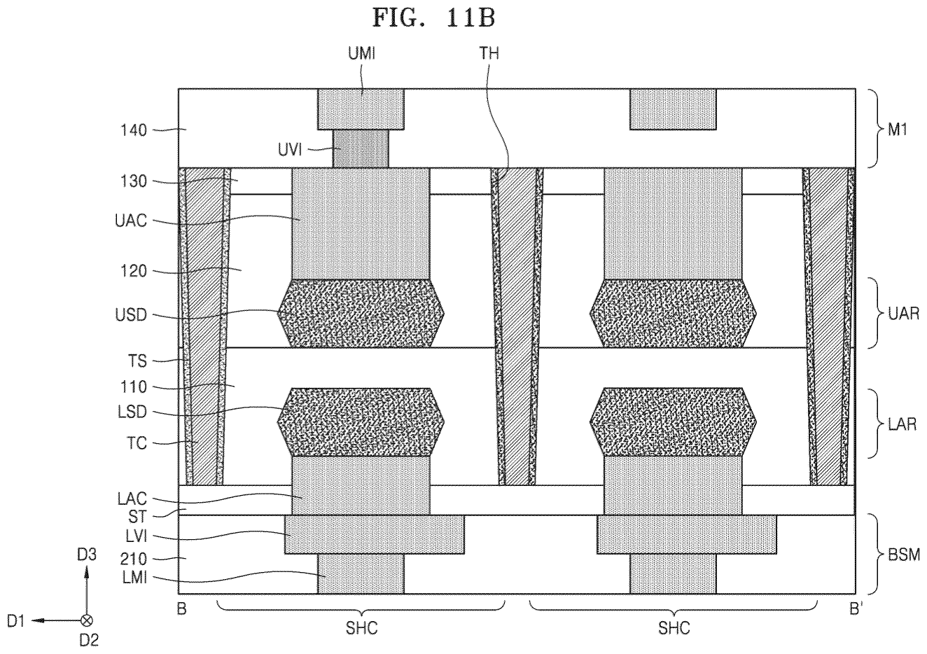

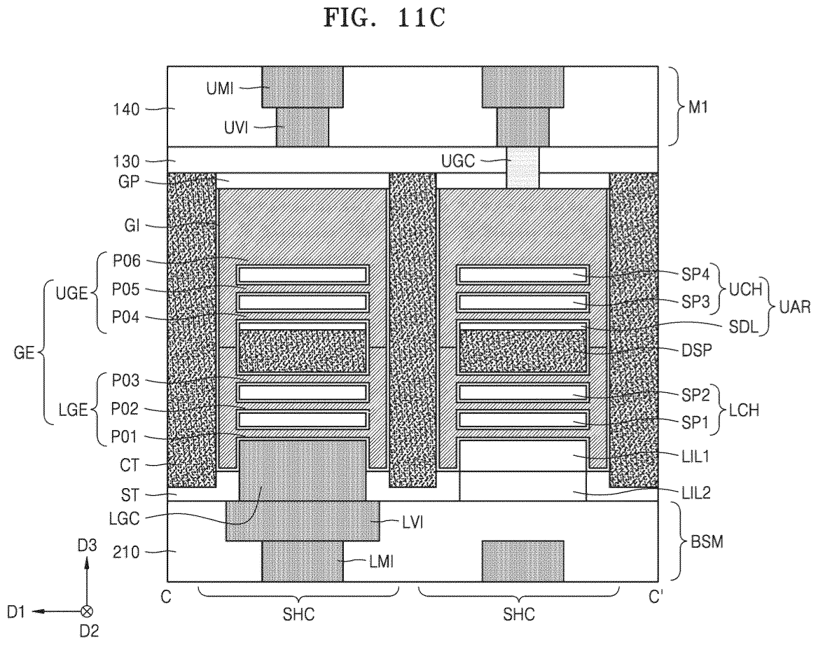

FIG. 10 is a plan view illustrating a three-dimensional semiconductor device according to an example embodiment. FIGS. 11A to 11C are cross-sectional views respectively taken along lines A-A′, B-B′, and C-C′ of FIG. 10.

Referring to FIGS. 10 to 11C, single-height cells SHC may be provided on a substrate 100. The substrate 100 may include a first surface 100a and a second surface 100b that face each other. A first side 100a may be a front side of the substrate 100, and a second side 100b may be a back side of the substrate 100. In an example embodiment, the substrate 100 may be an insulating substrate including a silicon-based insulating material (for example, silicon oxide and/or silicon nitride). In another example embodiment, the substrate 100 may be a semiconductor substrate including silicon, germanium, silicon germanium, or the like.

For example, the substrate 100 may include a first lower insulating layer LIL1 and a second lower insulating layer LIL2. The first lower insulating layer LIL1 may be provided on the second lower insulating layer LIL2. The first lower insulating layer LIL1 may include a silicon-based insulating material (for example, silicon oxide) and/or a semiconductor material (Si or SiGe). The second lower insulating layer LIL2 may include a silicon-based insulating material (for example, silicon oxide, silicon oxynitride, or silicon nitride).

Device isolation layers ST may be provided in the substrate 100. The device isolation layers ST may define the single-height cells SHC. In a plan view, the single-height cells SHC may be defined between device isolation layers ST that are adjacent to each other in a first direction D1. The device isolation layers ST may be arranged between a back metal layer BSM (described later) and through-conductive patterns TC (described layer). For example, the device isolation layers ST may include a silicon-based insulating material (for example, silicon oxide, silicon oxynitride, or silicon nitride).

In an example embodiment, each of the single-height cells SHC may be a logic cell that forms a logic circuit. Each of the single-height cells SHC may be a logic cell including a three-dimensional device. The single-height cells SHC may be arranged in the first direction D1.

Each of the single-height cells SHC may include a lower active region LAR and an upper active region UAR that are sequentially stacked on the substrate 100. One of the lower and upper active regions LAR and UAR may be a P-type metal-oxide-semiconductor field-effect transistor (PMOSFET) region, and the other may be an N-type metal-oxide-semiconductor field-effect transistor (NMOSFET) region. The lower active region LAR may be provided in a bottom tier of a front-end-of-line (FEOL) layer, and the upper active region UAR may be provided in a top tier of the FEOL layer. An NMOSFET and a PMOSFET of the lower and upper active regions LAR and UAR may be vertically stacked to form three-dimensionally stacked transistors. In an embodiment, the lower active region LAR may be an NMOSFET region, and the upper active region UAR may be a PMOSFET region. Each of the lower and upper active regions LAR and UAR may have a bar shape or a line shape extending in a second direction D2.

The lower active region LAR may include lower channel patterns LCH and lower source drain patterns LSD. The lower channel patterns LCH may be arranged between a pair of lower source drain patterns LSD. The lower channel patterns LCH may connect the pair of lower source drain patterns LSD to each other.

The lower channel patterns LCH may include a first semiconductor pattern SP1 and a second semiconductor pattern SP2 that are stacked spaced apart from each other. Each of the first and second semiconductor patterns SP1 and SP2 may include silicon (Si), germanium (Ge), or silicon germanium (SiGe). For example, each of the first and second semiconductor patterns SP1 and SP2 may include crystalline silicon. Each of the first and second semiconductor patterns SP1 and SP2 may be a nanosheet. For example, the lower channel patterns LCH may further include one or more semiconductor patterns that are stacked spaced apart from the second semiconductor pattern SP2.

The lower source drain patterns LSD may be provided on the substrate 100. Each of the lower source drain patterns LSD may be an epitaxial pattern formed through a selective epitaxial growth (SEG) process. For example, upper surfaces of the lower source drain patterns LSD may be higher than an upper surface of the second semiconductor pattern SP2 of the lower channel patterns LCH.

The lower source drain patterns LSD may be doped with a dopant and may have a first conductivity type. The first conductivity type may be an N-type or P-type. In the example embodiment, the first conductivity type may be an N-type. The lower source drain patterns LSD may include silicon (Si) and/or silicon germanium (SiGe).

A first interlayer insulating layer 110 may be provided on the lower source drain patterns LSD. The first interlayer insulating layer 110 may cover and be provided on the lower source drain patterns LSD.

Lower active contacts LAC may be provided under the lower source drain patterns LSD. The lower active contacts LAC may be electrically connected to the lower source drain patterns LSD. The lower active contacts LAC may be buried in the substrate 100. The lower active contacts LAC may extend vertically from the second side 100b to the first side 100a of the substrate 100. The lower active contacts LAC may include a metal selected from copper (Cu), aluminum (Al), ruthenium (Ru), cobalt (Co), tungsten (W), and molybdenum (Mo).

The upper active region UAR may be provided on the first interlayer insulating layer 110. The upper active region UAR may include upper channel patterns UCH and upper source drain patterns USD. The upper channel patterns UCH may vertically overlap the lower channel patterns LCH. The upper source drain patterns USD may vertically overlap the lower source drain patterns LSD. The upper channel patterns UCH may be arranged between a pair of upper source drain patterns USD. The upper channel patterns UCH may connect the pair of upper source drain patterns USD to each other.

The upper channel patterns UCH may include a third semiconductor pattern SP3 and a fourth semiconductor pattern SP4 that are stacked spaced apart from each other. The third and fourth semiconductor patterns SP3 and SP4 of the upper channel patterns UCH may include the same semiconductor material as the first and second semiconductor patterns SP1 and SP2 of the lower channel patterns LCH. Each of the third and fourth semiconductor patterns SP3 and SP4 may be a nanosheet. For example, the upper channel patterns UCH may further include one or more semiconductor patterns that are stacked spaced apart from the fourth semiconductor pattern SP4.

At least one dummy channel pattern DSP may be arranged between the lower channel patterns LCH and the upper channel patterns UCH disposed above the lower channel patterns LCH. A seed layer SDL may be arranged between the dummy channel pattern DSP and the upper channel patterns UCH.

The dummy channel pattern DSP may be spaced apart from the lower and upper source drain patterns LSD and USD. For example, the dummy channel pattern DSP may not be connected to any of the lower and upper source drain patterns LSD and USD. The dummy channel pattern DSP may include a semiconductor material such as silicon (Si), germanium (Ge), or silicon germanium (SiGe), or may include a silicon-based insulating material such as a silicon oxide layer or a silicon nitride layer. In an example embodiment, the dummy channel pattern DSP may include a silicon-based insulating material.

The upper source drain patterns USD may be provided on an upper surface of the first interlayer insulating layer 110. Each of the upper source drain patterns USD may be an epitaxial pattern formed through an SEG process. For example, upper surfaces of the upper source drain patterns USD may be higher than an upper surface of the fourth semiconductor pattern SP4 of the upper channel patterns UCH.

The upper source drain patterns USD may be doped with a dopant and have a second conductivity type. The second conductivity type may be different from the first conductivity type of the lower source drain patterns LSD. The second conductivity type may be a P-type. The upper source drain patterns USD may include silicon germanium (SiGe) and/or silicon (Si).

A plurality of gate electrodes GE may be provided on the single-height cells SHC. For example, the gate electrodes GE may be provided on the lower and upper channel patterns LCH and UCH that are stacked. In a plan view, the gate electrodes GE may have a bar shape extending in the first direction D1. The gate electrodes GE may vertically overlap the lower and upper channel patterns LCH and UCH that are stacked.

The gate electrodes GE may extend in a vertical direction (a third direction D3) from the first surface 100a of the substrate 100 to gate capping patterns GP. The gate electrodes GE may extend in the third direction D3 from the lower channel patterns LCH of the lower active region LAR to the upper channel patterns UCH of the upper active region UAR. The gate electrodes GE may extend in the third direction D3 from the first semiconductor patterns SP1 that are lowermost to the fourth semiconductor patterns SP4 that are uppermost.

The gate electrodes GE may be provided on a top surface, a bottom surface, and both side walls of each of the first to fourth semiconductor patterns SP1 to SP4. For example, transistors of the example embodiments may include three-dimensional field effect transistors (for example, multi-bridge channel field-effect transistors (MBCFETs) or gate-all-around field-effect transistors (GAAFETs)) in which channels are three-dimensionally surrounded by gate electrodes GE.

Each of the gate electrodes GE may include a lower gate electrode LGE provided in the bottom tier of the FEOL layer, that is, in the lower active region LAR, and an upper gate electrode UGE provided in the top tier of the FEOL layer, that is, in the upper active region UAR. The lower gate electrode LGE and the upper gate electrode UGE may vertically overlap each other. In an example embodiment, the lower gate electrode LGE and the upper gate electrode UGE may be connected to each other. For example, according to an example embodiment, the gate electrode GE may be a common gate electrode in which the lower gate electrode LGE provided on the lower channel patterns LCH and the upper gate electrode UGE provided on the upper channel patterns UCH are connected to each other.

The lower gate electrode LGE may include a first inner electrode PO1 provided between a first active pattern and the first semiconductor pattern SP1, a second inner electrode PO2 provided between the first semiconductor pattern SP1 and the second semiconductor pattern SP2, and a third inner electrode PO3 provided between the second semiconductor pattern SP2 and the dummy channel pattern DSP.

The upper gate electrode UGE may include a fourth inner electrode PO4 provided between the dummy channel pattern DSP (or the seed layer SDL) and the third semiconductor pattern SP3, a fifth inner electrode PO5 provided between the third semiconductor pattern SP3 and the fourth semiconductor pattern SP4, and an outer electrode PO6 provided on the fourth semiconductor pattern SP4.

A pair of gate spacers GS may be disposed on both side walls of the gate electrode GE. The pair of gate spacers GS may be disposed on both side walls of the outer electrode PO6. The gate spacers GS may extend in the first direction D1 along the gate electrode GE. Upper surfaces of the gate spacers GS may be higher than an upper surface of the gate electrode GE. The upper surfaces of the gate spacers GS may be coplanar with an upper surface of a second interlayer insulating layer 120. The gate spacers GS may include at least one selected from SiCN, SiCON, and SiN. In another example, the gate spacers GS may each include multiple layers including at least two selected from SiCN, SiCON, and SiN.

The gate capping patterns GP may be provided on the upper surfaces of the gate electrodes GE. The gate capping patterns GP may extend in the first direction D1 along the gate electrodes GE. For example, the gate capping patterns GP may include at least one selected from SiON, SiCN, SiCON, and SiN.

A gate insulating layer GI may be arranged between the gate electrodes GE and the first to fourth semiconductor patterns SP1 to SP4. The gate insulating layer GI may include a silicon oxide layer, a silicon oxynitride layer, and/or a high-k dielectric layer. In an embodiment, the gate insulating layer GI may include a silicon oxide layer that directly covers surfaces of the first to fourth semiconductor patterns SP1 to SP4, and a high-k dielectric layer provided on the silicon oxide layer. For example, the gate insulating layer GI may have a multi-layer structure including the silicon oxide layer and the high-k dielectric layer.

The high-k dielectric layer may include a high-k dielectric material having a higher dielectric constant than the silicon oxide layer. For example, the high-k dielectric material may include at least one selected from hafnium oxide (HfO₂), hafnium silicon oxide (HfSO₂), hafnium zirconium oxide (HfZrO₂), hafnium tantalum oxide (HfTaO₂), lanthanum oxide (LaO₂), zirconium oxide (ZrO₂), zirconium silicon oxide (ZrSO₂), tantalum oxide (TaO₂), titanium oxide (TiO₂), barium strontium titanium oxide (BaO₄SrTi), barium titanium oxide (BaTiO₃), strontium titanium oxide (SrTiO₃), lithium oxide (Li₂O), aluminum oxide, lead scandium tantalum oxide (Pb(Sc_{0.5}Ta_{0.5})O₃), and lead zinc niobate (PZN).

The second interlayer insulating layer 120 may be provided on the upper source drain patterns USD and the gate electrodes GE. The second interlayer insulating layer 120 may cover and be provided on the upper source drain patterns USD. A third interlayer insulating layer 130 may cover and be provided on the second interlayer insulating layer 120.

Upper active contacts UAC may be respectively electrically connected to the upper source and drain patterns USD through the second and third interlayer insulating layers 120 and 130. Upper surfaces of the upper active contacts UAC may be coplanar with an upper surface of the third interlayer insulating layer 130.

Upper gate contacts UGC may be electrically connected to the upper gate electrodes UGE through the third interlayer insulating layer 130 and the gate capping patterns GP. The upper active contacts UAC and the upper gate contacts UGC may each include a metal selected from copper (Cu), aluminum (Al), ruthenium (Ru), cobalt (Co), tungsten (W), and molybdenum (Mo).

Cutting patterns CT may be provided between the gate electrodes GE that are adjacent to each other in the first direction D1. The cutting patterns CT may separate the gate electrodes GE from each other. The gate electrodes GE may be separated apart from each other in the first direction D1 by the cutting patterns CT. The cutting patterns CT may each have a bar shape or a line shape extending in the second direction D2. The cutting patterns CT may include an insulating material such as silicon oxide and silicon nitride.

A fourth interlayer insulating layer 140 may be provided on the third interlayer insulating layer 130. A first metal layer M1 may be provided in the fourth interlayer insulating layer 140. The first metal layer M1 may include upper interconnections UMI. The first metal layer M1 may further include upper vias UVI. The upper vias UVI may electrically connect the upper interconnections UMI to the upper active contacts UAC or the upper gate contacts UGC. The upper interconnections UMI and the upper vias UVI may each include a metal selected from copper (Cu), aluminum (Al), ruthenium (Ru), cobalt (Co), tungsten (W), and molybdenum (Mo).

According to an example embodiment, the interconnector 20 may be an element of the three-dimensional semiconductor device. For example, the upper vias UVI may correspond to the reaction inhibitor 23 and the ruthenium via RV described with reference to FIG. 2, the interlayer insulating layer 140 may correspond to the dielectric layer 22 described with reference to FIG. 2, and the upper active contacts UAC may correspond to the metal layer 21 described with reference to FIG. 2. In addition, the upper vias UVI may correspond to the ruthenium via RV1 described with reference to FIG. 8, the interlayer insulating layer 140 may correspond to the dielectric layer 22 described with reference to FIG. 8, and the upper active contacts UAC may correspond to the metal layer 21 described with reference to FIG. 8.

Additional metal layers (for example, M2, M3, M4, etc.) may be stacked on the first metal layer M1. The first metal layer M1 and the additional metal layers (for example, M2, M3, M4, etc.) stacked on the first metal layer M1 may form a back-end-of-line (BEOL) layer of the three-dimensional semiconductor device. The additional metal layers (for example, M2, M3, M4, etc.) stacked on the first metal layer M1 may include routing interconnections to connect logic cells to each other.

A lower interlayer insulating layer 210 may be provided under the second surface 100b of the substrate 100. The back metal layer BSM may be provided in the lower interlayer insulating layer 210. The back metal layer BSM may include lower interconnections LMI. The back metal layer BSM may further include lower vias LVI. The lower vias LVI may electrically connect the lower interconnections LMI to the lower active contacts LAC, lower gate contacts LGC, or lower contact patterns.

The lower interconnections LMI and the lower vias LVI may each include a metal selected from copper (Cu), aluminum (Al), ruthenium (Ru), cobalt (Co), tungsten (W), and molybdenum (Mo).

Additional lower metal layers may be stacked under the back metal layer BSM. In an example embodiment, the additional lower metal layers may include a power transmission network. The power transmission network may include an interconnection network for applying a source voltage VSS and a drain voltage VDD to the back metal layer BSM.

The source voltage VSS and the drain voltage VDD may be applied to the back metal layer BSM through the power transmission network. Referring back to FIG. 11A, one of the source voltage VSS or the drain voltage VDD may be applied to the lower source drain patterns LSD through the lower interconnections LMI, the lower vias LVI, and the lower active contacts LAC. The other voltage may be applied from the back metal layer BSM to the first metal layer M1 through power tap cells. The other voltage applied to the first metal layer M1 through the power tap cells may be applied to the upper source drain patterns USD through the upper interconnections UMI, the upper vias UVI, and the upper active contacts UAC. The power tap cells may be arranged between adjacent single-height cells SHC.

The through-conductive patterns TC may penetrate the first, second, and third interlayer insulating layers 110, 120, and 130 in the vertical direction (the third direction D3). The through-conductive patterns TC may be provided in through-holes TH that penetrate the first, second, and third interlayer insulating layers 110, 120, and 130 in the vertical direction. The through-conductive patterns TC may be arranged without restrictions from a planar perspective. For example, although FIG. 10 illustrates that the through-conductive patterns TC are two-dimensionally arranged in the first and second directions D1 and D2, embodiments are not limited thereto.

The through-conductive patterns TC may penetrate the first, second, and third interlayer insulating layers 110, 120, and 130 to electrically connect the first metal layer M1 and the back metal layer BSM to each other. The through-conductive patterns TC may be electrically connected to the first metal layer M1 through the upper vias UVI.

As described above, according to the one or more of the above example embodiments, the reliability and durability of the interconnector may be improved because metal oxides are not included in the hole of the interconnector.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. An interconnector comprising:
a metal layer;
a dielectric layer on the metal layer and comprising a hole exposing a surface of the metal layer;
a reaction inhibitor in the hole and contacting a lateral surface of the dielectric layer;
a first ruthenium via in the hole, the first ruthenium via contacting the metal layer and the reaction inhibitor; and
a second ruthenium via in the hole, the second ruthenium via contacting the first ruthenium via and the reaction inhibitor, a resistivity of the second ruthenium via being greater than a resistivity of the first ruthenium via.

2. The interconnector of claim 1, wherein a ratio of the resistivity of the second ruthenium via to the resistivity of the first ruthenium via is from 1.2 to 3.

3. The interconnector of claim 1, wherein the resistivity of the second ruthenium via is less than or equal to 25 μΩ·cm.

4. The interconnector of claim 1, wherein a thickness of the first ruthenium via is less than a thickness of the second ruthenium via.

5. The interconnector of claim 1, wherein a ratio of a thickness of the second ruthenium via to a thickness of the first ruthenium via is from 2 to 20.

6. The interconnector of claim 1, wherein the first ruthenium via has a thickness less than or equal to 1.5 nm.

7. The interconnector of claim 1, wherein at least one of a width of the hole and a thickness of the hole is less than or equal to 10 nm.

8. The interconnector of claim 1, wherein the first ruthenium via is based on reduction, and
wherein the second ruthenium via is based on oxidation.

9. The interconnector of claim 1, wherein a size of grains included in the first ruthenium via is different from a size of grains included in the second ruthenium via

10. The interconnector of claim 1, wherein a size of grains included in the first ruthenium via is less than a size of grains included in the second ruthenium via.

11. The interconnector of claim 1, wherein an arithmetic average roughness (Ra) of the second ruthenium via is less than or equal to 1 nm.

12. The interconnector of claim 1, wherein at least one of the first ruthenium via and the second ruthenium via does not have an empty space.

13. The interconnector of claim 1, wherein an oxide of a metal of the metal layer is not included in the hole.

14. The interconnector of claim 1, wherein the metal layer comprises at least one of copper (Cu), aluminum (Al), cobalt (Co), tungsten (W), ruthenium (Ru), and molybdenum (Mo).

15. The interconnector of claim 1, wherein the reaction inhibitor comprises at least one of tris(dimethylamino)methylsilane (TDMAMS), bis(N,N-dimethylamino)-dimethylsilane (DMADMS), dimethylamino-trimethylsilane (DMATMS), tert-Butyl chloride, tert-Butyl bromide, and tert-Butyl iodide.

16. An electronic apparatus comprising:
a device layer comprising at least one of a transistor, a capacitor, and a resistor; and
an interconnector connected to the device layer, the interconnector comprising:
a metal layer;
a dielectric layer on the metal layer and comprising a hole exposing a surface of the metal layer;
a reaction inhibitor in the hole and contacting a lateral surface of the dielectric layer;
a first ruthenium via in the hole, with the first ruthenium via contacting the metal layer and the reaction inhibitor; and
a second ruthenium via in the hole, with the second ruthenium via contacting the first ruthenium via and the reaction inhibitor, a resistivity of the second ruthenium via being greater than a resistivity of the first ruthenium via.

17. A method of manufacturing an interconnector, the method comprising:
forming a dielectric layer on a metal layer, the dielectric layer comprising a hole;
forming a first ruthenium via in the hole based on a reducing reaction gas; and
forming a second ruthenium via in the hole based on an oxidizing reaction gas,
wherein a resistivity of the first ruthenium via is less than a resistivity of the second ruthenium via.

18. The method of claim 17, further comprising forming a reaction inhibitor on a lateral surface of the dielectric layer that is exposed through the hole.

19. The method of claim 17, wherein the resistivity of the second ruthenium via is less than or equal to 25 μΩ·cm.

20. The method of claim 17, wherein a thickness of the first ruthenium via is less than or equal to 1.5 nm.
